(19) United States
(12) Patent Application Publication
(10) Pub. No.: US 2008/0090158 A1
(43) Pub. Date: Apr. 17, 2008

(54) METHOD FOR DESIGNING AN INDEX PROFILE SUITABLE FOR ENCODING INTO A PHASE MASK FOR MANUFACTURING A COMPLEX OPTICAL GRATING

(75) Inventors: Yves Painchaud, Sillery (CA); Michel Morin, Sillery (CA)

Correspondence Address: DARBY & DARBY P.C., P.O. BOX 770, Church Street Station, New York, NY, 10008-0770, US

(73) Assignee: Teraxion Inc., Sainte-Foy (CA)

(21) Appl. No.: 11/932,557

(22) Filed: Oct. 31, 2007

Related U.S. Application Data
(63) Continuation-in-part of application No. 11/372,454, filed on Mar. 8, 2006.
(60) Provisional application No. 60/659,082, filed on Mar. 8, 2005.

(51) Int. Cl. G03F 1/00

(52) U.S. Cl. 430/5

(57) ABSTRACT

A method for designing an index profile suitable for encoding into a phase mask for manufacturing a complex optical grating is provided. The optical grating corresponds to a target index profile defining a target spectral response. A modified index profile is set equal to the target index profile and expressed as a function of an apodization and phase profiles. The modified index profile is iteratively further modified in order to provide the index profile suitable for encoding in the phase mask. This process creates side bands outside of a spectral region of interest, while maintaining the target spectral response within the spectral region of interest.

### CROSS-RELATED APPLICATIONS

The present application is a continuation-in-part of U.S. patent application Ser. No. 11/372,454, filed on Mar. 8, 2006 under priority of U.S. provisional patent application Ser. No. 60/659,082, filed on Mar. 8, 2005.

### FIELD OF THE INVENTION

The present invention relates to the field of optical components and more particularly concerns a method for designing an index profile suitable for encoding into a phase mask for use to photoinduce optical gratings having complex spectral response.

### BACKGROUND OF THE INVENTION

The Fiber Bragg grating (FBG) is a well established technology for applications in optical telecommunications, especially for Wavelength-Division-Multiplexing (WDM). Basically, a FBG reflects light propagating into an optical fiber at a wavelength known as the Bragg wavelength, which is determined by the period of the grating and the fiber effective index. A chirped FBG, in which the grating period varies as a function of the position along the fiber, is a well known solution for compensating the chromatic dispersion of an optical fiber link (see for example F. Ouellette, “Dispersion cancellation using linearly chirped Bragg grating filters in optical waveguides,” Opt. Lett., Vol. 12, pp. 847-849 (1987); and R. Kashyap, “Fiber Bragg gratings”, Academic Press, 458p. (1999)). Such a grating can compensate for the dispersion accumulated over an optical fiber link by providing a group delay that varies as a function of wavelength in a manner opposite to that of the group delay in the fiber link.

From the many available methods for the photo-inscription of FBGs, the use of a phase mask is recognized as the best choice for obtaining good optical performance (see for example U.S. Pat. No. 5,367,588 (HILL et al.) and U.S. Pat. No. 5,327,515 (ANDERSON et al.). The phase mask acts as a master that is used to replicate FBGs with the same optical characteristics on pieces of optical fiber in a fast and repeatable way, allowing for efficient mass production. The phase mask can contain all the information about the FBG to be written or only part of it, depending on the desired balance between ease of fabrication and flexibility.

Although the use of a phase mask was initially limited to the inscription of the period profile of a single channel FBG, recent advances have made possible the encoding of the multi-channel character through phase sampling, as shown in U.S. Pat. No. 6,707,967 (ROTHENBERG et al.). In a further development, the in-mask encoding of the apodization profile of the FBG was proposed in U.S. patent application published under No. 2004/0264858 (ROTHENBERG). The whole information related to a FBG can thus be encoded into the phase mask, hence maximizing its manufacturability. In practice, this means that a binary phase mask with properly positioned groove edges can be used to write a FBG with a complex spectral response using a uniform exposition to actinic radiation.

Complex phase mask however imposes some constraints on the physical characteristics of the FBGs. Very complex phase structures can be encoded into the phase mask but the apodization profile is typically required to be exempt of fine structures. Furthermore, the phase profile should be compatible with the diffraction effects taking place between the phase mask and the fiber. Noteworthy, some spatial frequencies in the phase spectrum cannot be transferred from the mask to the fiber. These particular spatial frequencies must be avoided as far as possible.

U.S. Pat. No. 7,200,301 (BURYAK) teaches a technique for designing multi-channel optical gratings, where a grating design is iteratively modified so that the response function of the modified grating has a desired response characteristic in at least one portion of the spectral domain other than the functional spectral domain. While the technique of BURYAK could be useful to obtain an index function having smoother apodization characteristics, it requires repeatedly solving an inverse scattering problem which can involve complex and time consuming calculations.

There remains therefore a need for a technique for designing and manufacturing phase masks for manufacturing complex optical gratings which alleviates at least some of the drawbacks of the prior art.

### SUMMARY OF THE INVENTION

In accordance with one aspect of the invention, there is provided a method for designing an index profile Suitable for encoding into a phase mask for manufacturing a complex optical grating. The optical grating corresponds to a target index profile having a Fourier spectrum and defining a target optical spectral response inside a spectral region of interest. The method includes the steps of:
(a) setting a modified index profile equal to the target index profile;
(b) expressing the modified index profile as a function of a modified apodization profile and a modified phase profile;
(c) filtering the modified phase profile in order to minimize phase periodicities therein, thereby obtaining a filtered phase profile;
(d) replacing the modified apodization profile by a smooth apodization profile, and replacing the modified phase profile by the filtered phase profile;
(e) calculating a Fourier spectrum of the modified index profile obtained through the replacing of step (d);

(f) calculating a hybrid index profile having a Fourier spectrum corresponding to a sum of the Fourier spectrum of the modified index profile outside the spectral region of interest with the Fourier spectrum of the target index profile within the spectral region of interest;
(g) setting the modified index profile equal to the hybrid index profile; and
(h) repeating steps (b) through (g) using the modified index profile obtained at step (g) as a starting point, until the index profile suitable for encoding into a phase mask is obtained.

In accordance with another aspect of the invention, there is also provided a method for manufacturing a phase mask for photoinducing a complex optical grating in a photosensitive medium. The complex optical grating corresponds to a target index profile having a Fourier spectrum and defining a target optical spectral response inside a spectral region of interest. The method includes the steps of:
A) designing an index profile suitable for encoding into a phase mask, said designing comprising the sub-steps of:
   (a) setting a modified index profile equal to the target index profile;
   (b) expressing the modified index profile as a function of a modified apodization profile and a modified phase profile;
   (c) filtering the modified phase profile in order to minimize phase periodicities therein, thereby obtaining a filtered phase profile;
   (d) replacing the modified apodization profile by a smooth apodization profile, and replacing the modified phase profile by the filtered phase profile;
   (e) calculating a Fourier spectrum of the modified index profile obtained through the replacing of sub-step (d);
   (f) calculating a hybrid index profile having a Fourier spectrum corresponding to a sum of the Fourier spectrum of the modified index profile outside the spectral region of interest with the Fourier spectrum of the target index profile within the spectral region of interest;
   (g) setting the modified index profile equal to the hybrid index profile; and
   (h) repeating sub-steps (b) through (g) using the modified index profile obtained at sub-step (g) as a starting point until the index profile suitable for encoding into a phase mask is obtained; and
B) encoding a phase mask according to the index profile suitable for encoding.

In accordance with yet another aspect of the invention, there is also provided a method for manufacturing a complex optical grating in a photosensitive medium, the complex optical grating corresponding to a target index profile having a Fourier spectrum and defining a target optical spectral response inside a spectral region of interest. The method includes the steps of:
A) designing an index profile suitable for encoding into a phase mask, the designing comprising the sub-steps of:
   (a) setting a modified index profile equal to the target index profile;
   (b) expressing the modified index profile as a function of a modified apodization profile and a modified phase profile;
   (c) filtering the modified phase profile in order to minimize phase periodicities therein, thereby obtaining a filtered phase profile;
   (d) replacing the modified apodization profile by a smooth apodization profile, and replacing the modified phase profile by the filtered phase profile;
   (e) calculating a Fourier spectrum of the modified index profile obtained through the replacing of sub-step (d);
   (f) calculating a hybrid index profile having a Fourier spectrum corresponding to a sum of the Fourier spectrum of the modified index profile outside the spectral region of interest with the Fourier spectrum of the target index profile within the spectral region of interest;
   (g) setting the modified index profile equal to the hybrid index profile; and
   (h) repeating sub-steps (b) through (g) using the modified index profile obtained at sub-step (g) as a starting point until said index profile suitable for encoding into a phase mask is obtained;
B) encoding a phase mask according to said index profile suitable for encoding; and
C) photoinducing said complex grating in the photosensitive medium using said phase mask.

Other features and advantages of the present invention will be better understood upon reading of preferred embodiments thereof with reference to the appended drawings.

### BRIEF DESCRIPTION OF THE DRAWINGS

FIGS. 1A to 1G are graphs respectively showing the apodization profile (FIG. 1A), the period profile (FIG. 1B), the phase spectrum as a function of spatial frequency (FIG. 1C), the reflectivity spectra on a large and a small wavelength scale (FIGS. 1D and 1E), the group delay spectra (FIG. 1F) and the group delay ripple (FIG. 1G), of a 51-channel grating corresponding to the mathematical sum of corresponding sub-gratings.

FIGS. 2A to 2G are similar graphs as those of FIGS. 1A to 1G for the same 51-channel grating after iteratively translating apodization features into side bands.

FIGS. 3A and 3B are schematic illustrations of two variants of a system for photoinducing an optical grating in a photosensitive medium, each including a phase mask.

### DESCRIPTION OF PREFERRED EMBODIMENTS OF THE INVENTION

The present invention provides a method designing an index profile suitable for encoding into a phase mask, in order to allow the manufacturing of a complex optical grating in a photosensitive medium. Methods for manufacturing such a phase mask and for photoinducing a complex Bragg grating are also provided. Although the description below will mainly refer to FBGs, it will be understood by one skilled in the art that the present invention may be applied to the manufacturing of periodic refractive index profiles in any appropriate photosensitive medium, for example waveguides such as optical fibers and planar waveguides.

Complex phase masks have been part of many recent advances in FBG by providing an efficient fabrication of complex FBGs compatible with mass production.

As mentioned above, very complex phase structures can be encoded into the phase mask but the apodization profile is typically required to be exempt of fine structures. Furthermore, the phase profile should be compatible with the diffraction effects taking place between the phase mask and the fiber. Noteworthy, some spatial frequencies in the phase spectrum cannot be transferred from the mask to the fiber. These particular spatial frequencies must be avoided as far as possible.

The present invention advantageously provides a method for designing an index profile suitable for encoding in a phase mask for manufacturing optical gratings of any level of complexity.

The optical grating to be manufactured corresponds to a target index profile defining a target spectral response inside a spectral region of interest. It will be understood by one skilled in the art that in the context of FBGs, the index profile refers to the modulation of the effective index of the optical fiber. The target index profile may have been previously obtained in any appropriate manner, depending on the particularities of the grating and targeted use thereof.

In one embodiment, the target index profile is obtained by using a design technique such as those involving an inverse scattering algorithm. An example of such a technique is for example described in U.S. Pat. No. 7,200,301 (BURYAK). Another example is given in Assignee's provisional patent application 60/935,850, filed on Sep. 4, 2007.

Alternatively, a multi-channel grating could be obtained through the design of a number of individual sub-gratings, each corresponding to one channel. Each sub-grating is therefore equivalent to a single-channel grating providing the required spectral response for the corresponding channel only. The designing of single-channel gratings is well known to those skilled in the art. Preferably, each sub-grating is attributed an individual apodization profile and an individual phase profile, which are adjusted according to the desired spectral characteristics of the corresponding channel. These characteristics include the channel central wavelength and bandwidth, and may advantageously include dispersion characteristics such as the dispersion value and intra-channel dispersion slope. For applications in optical telecommunications, the bandwidth of each channel will be the same and their central wavelengths will be evenly spaced. A discussion on these concepts may for example be found in U.S. Pat. No. 6,865,319 (PAINCHAUD), which is incorporated herein by reference. The target index profile can then be based on the combination of the individual profiles of all the sub-gratings, and may for example include the mathematical sum of those individual profiles. It will be understood that the target profile may actually be mathematically represented in a number of fashion, depending on how the different terms are defined. It will also be understood that terms additional to the sub-grating profiles may be incorporated in the target profile, such as an index offset term.

For complex gratings, the target index profile often has physical characteristics that could be incompatible with the writing method. For example, a complex apodization profile including fast longitudinal variations along the optical axis can be technically difficult to encode in a phase mask. In accordance with one embodiment of the invention, a modified index profile is therefore determined, which provides the same spectral response as the target profile within a region of interest, yet has a smooth apodization profile. It will therefore be possible to encode this modified index profile in a phase mask using standard techniques while the apodization would be possible to be realized with means such as varying the UV power or using the moving mask method.

It will be understood by one skilled in the art that the spectral responses of the modified and target index profiles need not be absolutely identical, but will be considered as being the “same” if the reflectivity features of the corresponding grating are sufficiently similar for the purposes of the particular application the grating is to serve. The spectral region of interest will also be determined by the context of a particular application, and generally refers to the wavelength range within which the grating is to be used. For example, in the context of optical telecommunications, guided light beams usually have wavelengths within specific infrared communication bands; the effects of the multi-channel grating on light of a wavelength outside of this band will therefore have no impact on the operation of the system incorporating this grating. As will be seen further below for an embodiment of the present invention, this feature may be taken advantage of in order to determine the modified index profile.

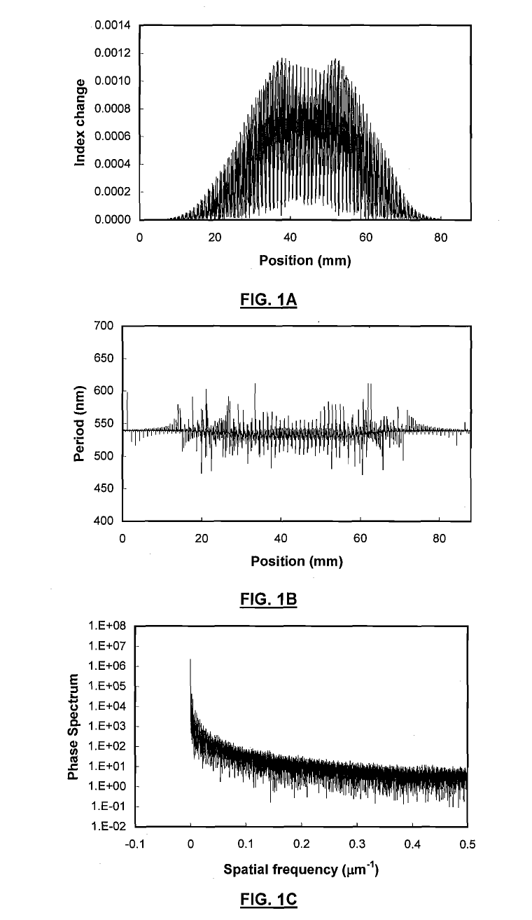

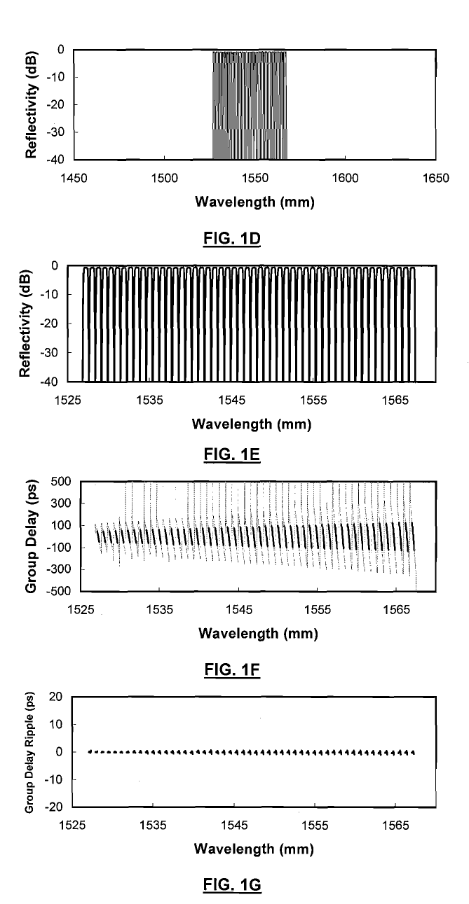

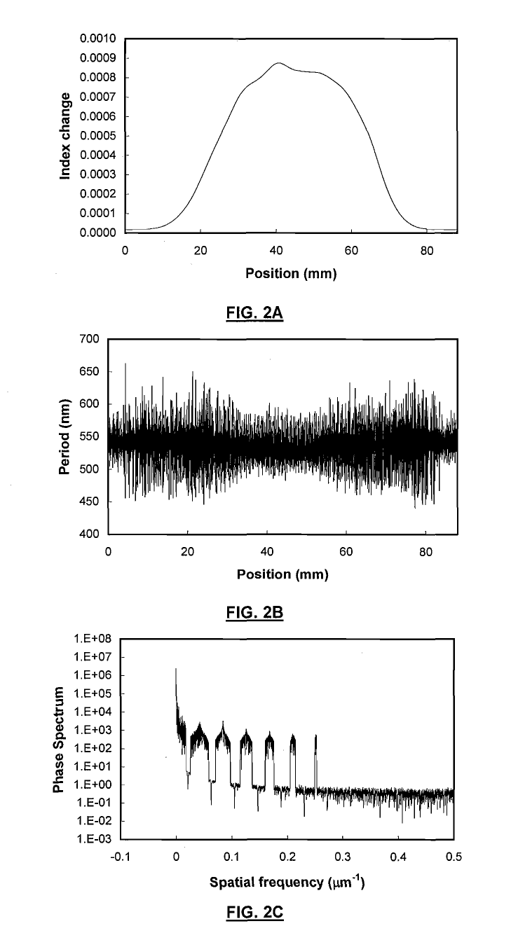

By way of example, FIGS. 1A to 1G show the physical and spectral profiles of a target index profile obtained after summing individual gratings, each associated with one of 51 channels. The apodization profile is shown in FIG. 1A, where fine structures are clearly seen. Fine structures are also seen in the period profile shown in FIG. 1B. In FIG. 1C, it can be seen that the Fourier spectrum of the phase shift is spread over many frequencies including some that could be problematic due to the mask-fiber transfer function. In FIG. 1D, one can see that no side band is produced by the summing process, only the 51 required peaks appear, as more clearly seen in FIG. 1E. Finally, FIGS. 1F and 1G show the group delay and group delay ripple spectra, respectively.

The FBG design depicted in FIGS. 1A through 1G presents two difficulties, assuming that a complex phase mask is to be used. Firstly, its apodization profile contains fine structures. Secondly, its phase profile contains periodicities that are difficult to encode into the phase mask. As can be seen from FIG. 1C, the FBG contains a rich spectrum and contains spatial frequencies close to the zeros of the transfer function that relates the phase profile of the phase mask to the phase profile of the FBG. The FBG phase profile is related to the mask phase profile through the following expression:
ℑ(Δθ)=ℑ(Δθₘ)·T (1)
where Δθ is the FBG phase shift profile, Δθₘ is the mask phase shift profile, T is the transfer function and ℑ is the Fourier operator. The phase shift profiles are related to the total phase profiles by:

$$\begin{matrix}θ ( z ) = \frac{2 π}{{p}_{av}} + Δθ ( z ) , & ( 2 ) \\ {θ}_{m} ( z ) = \frac{2 π}{{Λ}_{av}} + {Δθ}_{m} ( z ) & ( 3 )\end{matrix}$$

where pₐᵥ is the average period of the FBG and Λₐᵥ is the average period of the phase mask. The local periods in the FBG and the phase mask are related to the total phases by the following expressions:

$$\begin{matrix}p ( z ) = 2 π \cdot {[ \frac{ⅆ θ ( z )}{ⅆ z} ]}^{- 1} , & ( 4 ) \\ Λ ( z ) = 2 π \cdot {[ \frac{ⅆ {θ}_{m} ( z )}{ⅆ z} ]}^{- 1} . & ( 5 )\end{matrix}$$

The transfer function is given by:
T=2 cos(πdz f), (6)
where f is the spatial frequency and dz is the distance between the two UV writing beams at the phase mask surface that cross and interfere in the fiber core. Since the transfer function is a cosine, some spatial frequencies correspond to vanishing transfer efficiencies.

The target index profile can be expressed as:
Δn_{struct}(z)=Δn_{offset}+Δnₐ(z)e^{iθ(z)} (7)
where Δnₐ(z) and θ(z) are the apodization and phase profiles of the target index profile respectively and Δn_{offset} is the index offset required to make the total index change strictly positive.

To mitigate the two problems discussed above, it is possible to add some side band gratings. In this case, a modified index profile Δn_{struct,mod}(z) is obtained and is mathematically expressed by:
Δn_{struct,mod}(z)=Δn_{offset}+Δnₐ(z)·exp(iθ(z))+Δnₛ(z)·exp(iθₛ(z)) (8)
where the last term of the equation represents the side band gratings that could be added without affecting the optical properties within the spectral range of interest. Equation (8) can in turn be expressed in terms of modified apodization and phase profiles:
Δn_{struct,mod}(z)=Δn_{offset}+Δñₐ(z)·exp(iθₜ(z)). (9)

If the side bands are properly chosen, the modified apodization profile Δñₐ(z) contains no fine structures and the modified phase profile θₜ(z) contains no problematic periodicities close to the zeros of the transfer function.

In order to ensure that the side bands change the optical properties of the optical grating only outside the spectral region of interest, it is useful to consider the Fourier spectrum of the target index profile given by Equation (7). Let ΔN_{struct}(f) be the Fourier spectrum of the target profile of the optical grating:
ΔN_{struct}(f)=ℑ{Δn_{struct}(z)}, (10)
where ℑ is the Fourier operator; it is found that ΔN_{struct}(f) is non zero only within a certain range of spatial frequencies (between fₘᵢₙ and fₘₐₓ). The side bands to be added will not affect the optical properties of the optical grating within the spectral region of interest if their Fourier spectrum is zero within the range between fₘᵢₙ and fₘₐₓ. It is well known that the Fourier spectrum of a low reflectivity FBG mimics quite well its optical characteristics. Accordingly, for low reflectivity FBG, keeping unaffected the Fourier spectrum of the FBG within a certain region (between fₘᵢₙ and fₘₐₓ) ensure keeping intact its optical characteristics (within a corresponding optical region). For a strong FBG, its Fourier spectrum does not well mimic its optical characteristics but its remains true that a given region of its Fourier spectrum is responsible for its optical characteristics within a corresponding region of interest. Accordingly, still for a high reflectivity FBG, keeping unaffected its Fourier spectrum within a certain region (between fₘᵢₙ and fₘₐₓ) ensure keeping unaffected its optical characteristics within a corresponding optical spectral range.

In accordance with one embodiment of the invention, there is therefore provided a method for designing an index profile suitable for encoding into a phase mask which makes use of this advantage of side bands generated outside the spectral region of interest.

The method includes a first step of (a) setting a modified index profile equal to the target index profile, that is, the index profile of the grating without any side bands. Using the conventions defined above, this can be expressed as:
Δn_{struct,mod}(z)=Δn_{struct}(z) (11)

In the next step (b), the modified index profile is then expressed as a function of a modified apodization profile and a modified phase profile Δnₘ(z) and θₘ(z). It will also be understood that, as for the target profile (see Equation (7)), terms additional to the apodization and phase profiles may be incorporated in the modified index profile additionally thereto, such as an index offset term. In the current embodiment, the modified index profile is for example expressed as:
Δn_{struct,mod}(z)=Δn_{offset}+Δnₘ(z)·exp(iθₘ(z)) (12)

In the next step (c), a filtered phase profile θ_{f}(z) is obtained by filtering out the phase periodicities required to be minimized from the modified phase profile. This is preferably accomplished by calculating a phase shift profile associated with the phase profile, for example using Equation (2), calculating a Fourier spectrum of the phase shift profile, and filtering this Fourier spectrum of the phase shift profile through a filter function:
ℑ{θ_{f}(z)}=ℑ{θₘ(z)}·F(f). (13)

The filter function F(f) can be equal to 1 except for the spatial frequencies where the phase periodicities are to be filtered out, where it is set to 0. The filtering can be more sophisticated and achieved to favor spatial frequencies that are far from the zeros of the mask-fiber transfer function. An appropriate weighting of the different components of the phase shift spectrum can be done to minimize the adverse effect of the mask-fiber transfer function. It is to be noted that the filtering is preferably applied to the phase shift profile rather than on the total phase profile, although for simplicity in the notation of Equation (13) it is written to be applied to the total phase profile.

The next step (d) involves changing the modified index profile so that the modified apodization profile Δnₘ(z) is replaced by another apodization profile Δñₐ(z), and the modified phase profile θₘ(z) is replaced by the filtered phase profile θ_{f}(z):
Δn_{struct,mod}(z)=Δn_{offset}+Δñₐ(z)·exp(iθ_{f}(z)). (14)

At this step, the modified index profile may have quite modified spectral characteristics, even within the spectral region of interest. The smooth apodization profile Δñₐ(z) can be predetermined at the onset of the iterative process. It can also be different for each iteration, for example by setting Δñₐ(z) to be equal to Δnₘ(z) smoothed spatially.

According to the next step (e) of the method, a Fourier spectrum of the modified index profile obtained after the replacing of step (d) is calculated:
ΔN_{struct,mod}(f)=ℑ{Δn_{struct,mod}(z)}, (15)

In the next step (f), a hybrid index profile is defined by having a Fourier spectrum corresponding to the Fourier spectrum of the modified index profile outside the region of interest and to the Fourier spectrum of the target index profile within the region of interest. This can be expressed as:
ΔN_{hybrid}(f)=ΔN_{struct,mod}(f<fₘᵢₙ,f>fₘₐₓ)+ΔN_{struct}(fₘᵢₙ<f<fₘₐₓ). (16)

In other words, the hybrid grating index profile is the original one from which are added some side bands generated by step (d).

The next step (g) of the method involves setting the modified index profile equal to the hybrid index profile:
Δn_{struct,mod}(z)=ℑ⁻¹{ΔN_{hybrid}(f)}. (17)

At this step, the optical characteristics are the same than those of the target index profile within the spectral range of interest and include some side bands outside the spectral range of interest. Its apodization profile is not necessarily free of fine structures but has less such structures than the target index profile. In the same manner, it is not necessarily free of phase periodicities required to be filtered out but has less than the target index profile. This is why steps (b) through (g) are repeated many times, each time using the modified index profile obtained at step is (g) as a starting point, until the modified index profile is considered suitable for encoding into a phase mask, that is, sufficiently free of fine-structured apodization and phase periodicities required to be filtered out. The smooth apodization profile Δñₐ(z) and the filter function F(f) are chosen to permit the convergence of the iterative process.

This design method can be applied to any complex FBG for which some physical characteristic is to be modified while optical characteristics are required to stay the same within a certain region of interest. It is an efficient design method and involves efficient numerical calculation, noteworthy through the use of Fast Fourier Transforms.

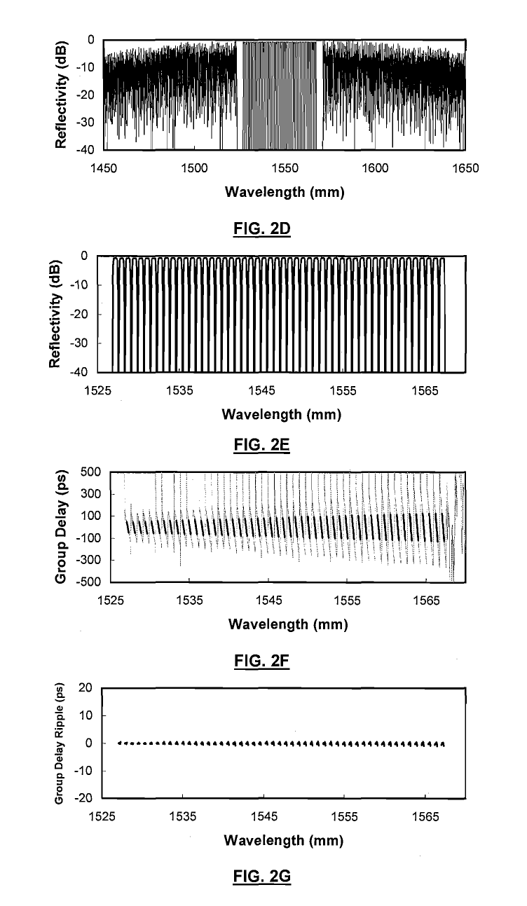

FIGS. 2A to 2G show the same graphs as FIGS. 1A to 1G after the iterative process is applied. It can be seen in FIG. 2A that a smooth apodization profile is obtained. In FIG. 2C, one can see that the spectrum of the phase profile was modified such as to avoid most of the components near the zeros of the mask-fiber transfer function occurring at spatial frequencies of 0.021, 0.063, 0.105, 0.147, 0.189, 0.231 and 0.273 μm⁻¹ in this case. Side bands are created by this process as can be seen in FIG. 2D, although not affecting the optical characteristics within the spectral region of interest as can be seen in FIGS. 2E, 2F and 2G.

In accordance with another aspect of the invention, there is provided a method for manufacturing a phase mask for photoinducing a complex optical grating into a photosensitive medium. This method includes as a first step the designing of an index profile suitable for encoding, as described above. The method next includes a step of encoding the phase mask according to the index profile as designed. This step is preferably accomplished through the use of a transfer function as defined at equation (6) above.

In accordance with yet another aspect of the invention, there is provided a method for manufacturing a complex optical grating in a photosensitive medium. This method includes the manufacturing of a phase mask according to the preceding method, and the use of this phase mask to photoinduce the grating in the photosensitive medium.

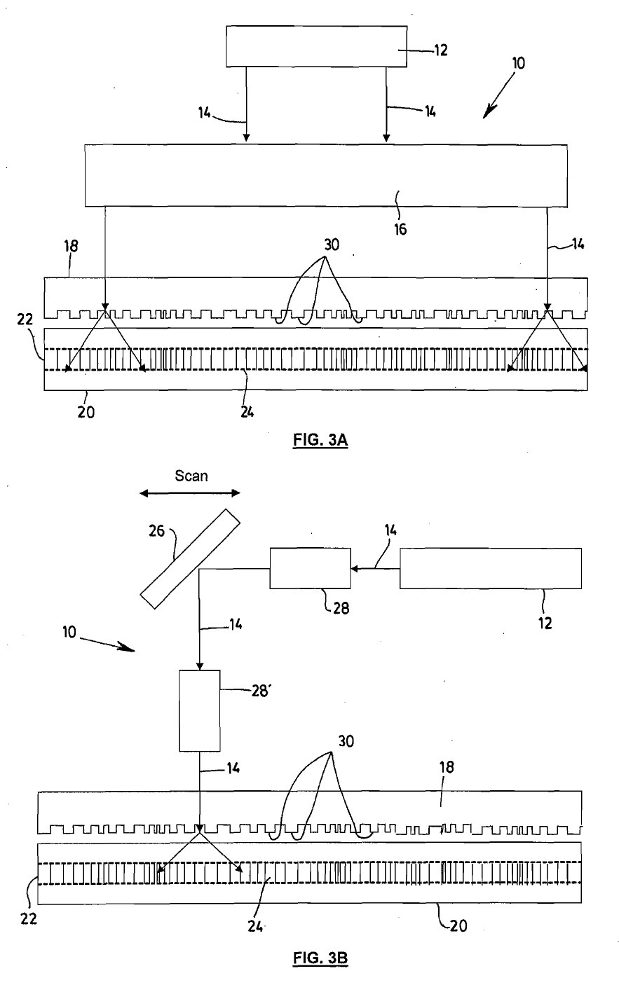

Referring to FIG. 3A, there is shown a first example of an optical system 10 which may be used in this context. It first includes a writing laser 12 providing actinide radiation, preferably a UV light beam 14. Optionally, the UV light beam 14 may be shaped by appropriate shaping optics 16 as is well known to those skilled in the art. The light beam 14 impinges transversally on the back of the phase mask 18. In the present case, the light beam 14 is expanded so as to have a width spanning the length of the phase mask 18. The phase mask 18 diffracts the radiation from the UV light beam into bright and dark fringes in a pattern corresponding to the target index profile, and the diffracted light impinges on the photosensitive medium which is disposed along the phase mask 18 in close proximity thereto. In the illustrated embodiment, the photosensitive medium is a length of optical fiber 20. The diffracted light photoinduces a refractive index modulation corresponding to the target profile in the core 22 of the optical fiber 20, this modulation defining the optical grating 24 after post-processing of the fiber as is well known in the art.

Referring to FIG. 3B, there is shown a system 10 according to an alternate embodiment. The system differs from the set up of FIG. 9A in that the UV light beam is scanned along the length of the phase mask instead of expanded for exposure of the entire phase mask. The system 10 is therefore provided with a scanning assembly including a moving mirror 26 and appropriate shaping optics 28 and 28′ upstream and downstream thereof, respectively.

Numerous modifications could be made to the embodiments above without departing from the scope of the present invention as defined in the appended claims.

1. A method for designing an index profile suitable for encoding into a phase mask for manufacturing a complex optical grating, said optical grating corresponding to a target index profile having a Fourier spectrum and defining a target optical spectral response inside a spectral region of interest, the method comprising the steps of:
(a) setting a modified index profile equal to said target index profile;
(b) expressing said modified index profile as a function of a modified apodization profile and a modified phase profile;
(c) filtering the modified phase profile in order to minimize phase periodicities therein, thereby obtaining a filtered phase profile;
(d) replacing the modified apodization profile by a smooth apodization profile, and replacing the modified phase profile by the filtered phase profile;
(e) calculating a Fourier spectrum of the modified index profile obtained through the replacing of step (d);
(f) calculating a hybrid index profile having a Fourier spectrum corresponding to a sum of said Fourier spectrum of the modified index profile outside said spectral region of interest with said Fourier spectrum of said target index profile within said spectral region of interest;
(g) setting the modified index profile equal to the hybrid index profile; and
(h) repeating steps (b) through (g) using the modified index profile obtained at step (g) as a starting point until said index profile suitable for encoding into a phase mask is obtained.

2. The method according to claim 1, wherein step (b) comprises expressing said modified index profile as:
Δn_{struct,mod}(z)=Δn_{offset}+Δnₘ(z)·exp(iθₘ(z))
wherein Δn_{struct,mod}(z) is the modified index profile, Δn_{offset} is an index offset making the modified index profile strictly positive, Δnₘ(z) is the modified apodization profile, and θₘ(z) is the modified phase profile.

3. The method according to claim 1, wherein the filtering of step (c) comprises the substeps of:
i. calculating a phase shift profile associated with the phase profile;
ii. calculating a Fourier spectrum of said phase shift profile; and
iii. filtering said Fourier spectrum of the phase shift profile through a filter function.

4. The method according to claim 3, wherein said filter function is set to 0 for spatial frequencies where said phase periodicities are present, and set to 1 otherwise.

5. The method according to claim 1, wherein the smooth apodization profile of step (d) is set to a predetermined profile or to a spatially smoothed version of the modified apodization profile.

6. The method according to claim 1, wherein the repeating of step (h) is carried out until the modified apodization profile is substantially free of fine structures and of phase periodicities.

7. A method for manufacturing a phase mask for photoinducing a complex optical grating in a photosensitive medium, said complex optical grating corresponding to a target index profile having a Fourier spectrum and defining a target optical spectral response inside a spectral region of interest, the method comprising the steps of:
A) designing an index profile suitable for encoding into a phase mask, said designing comprising the sub-steps of:
(a) setting a modified index profile equal to said target index profile;
(b) expressing said modified index profile as a function of a modified apodization profile and a modified phase profile;
(c) filtering the modified phase profile in order to minimize phase periodicities therein, thereby obtaining a filtered phase profile;
(d) replacing the modified apodization profile by a smooth apodization profile, and replacing the modified phase profile by the filtered phase profile;
(e) calculating a Fourier spectrum of the modified index profile obtained through the replacing of sub-step (d);
(f) calculating a hybrid index profile having a Fourier spectrum corresponding to a sum of said Fourier spectrum of the modified index profile outside said spectral region of interest with said Fourier spectrum of said target index profile within said spectral region of interest;
(g) setting the modified index profile equal to the hybrid index profile; and
(h) repeating sub-steps (b) through (g) using the modified index profile obtained at sub-step (g) as a starting point until said index profile suitable for encoding into a phase mask is obtained; and
B) encoding a phase mask according to said index profile suitable for encoding.

8. The method according to claim 7, wherein sub-step A)(b) comprises expressing said modified index profile as:
Δn_{struct,mod}(z)=Δn_{offset}+Δnₘ(z)·exp(iθₘ(z))
wherein Δn_{struct,mod}(z) is the modified index profile, Δn_{offset} is an index offset making the modified index profile strictly positive, Δnₘ(z) is the modified apodization profile, and θₘ(z) is the modified phase profile.

9. The method according to claim 7, wherein the filtering of sub-step A)(c) comprises the substeps of:
iv. calculating a phase shift profile associated with the phase profile;
v. calculating a Fourier spectrum of said phase shift profile; and
vi. filtering said Fourier spectrum of the phase shift profile through a filter function.

10. The method according to claim 9, wherein said filter function is set to 0 for spatial frequencies where said phase periodicities are present, and set to 1 otherwise.

11. The method according to claim 7, wherein the smooth apodization profile of sub-step A)(d) is set to a predetermined profile or to a spatially smoothed version of the modified apodization profile.

12. The method according to claim 7, wherein the repeating of sub-step A)(h) is carried out until the modified apodization profile is substantially free of fine structures and of phase periodicities.

13. The method according to claim 7, wherein the encoding of step B) comprises manufacturing said phase mask with corrugations having a phase profile related to the index profile suitable for encoding through a transfer function.

14. The method according to claim 13, wherein said transfer function is given by:
T=2 cos(πdz f)
where f is a spatial frequency and dz is a distance between two points along the phase mask from which pass two beams interfering in the photosensitive medium at a position z.

15. A method for manufacturing a complex optical grating in a photosensitive medium, said complex optical grating corresponding to a target index profile having a Fourier spectrum and defining a target optical spectral response inside a spectral region of interest, the method comprising the steps of:
A) designing an index profile suitable for encoding into a phase mask, said designing comprising the sub-steps of:
(a) setting a modified index profile equal to said target index profile;
(b) expressing said modified index profile as a function of a modified apodization profile and a modified phase profile;
(c) filtering the modified phase profile in order to minimize phase periodicities therein, thereby obtaining a filtered phase profile;
(d) replacing the modified apodization profile by a smooth apodization profile, and replacing the modified phase profile by the filtered phase profile;
(e) calculating a Fourier spectrum of the modified index profile obtained through the replacing of sub-step (d);
(f) calculating a hybrid index profile having a Fourier spectrum corresponding to a sum of the Fourier spectrum of the modified index profile outside said spectral region of interest with said Fourier spectrum of said target index profile within said spectral region of interest;
(g) setting the modified index profile equal to the hybrid index profile; and
(h) repeating sub-steps (b) through (g) using the modified index profile obtained at sub-step (g) as a starting point until said index profile suitable for encoding into a phase mask is obtained;
B) encoding a phase mask according to said index profile suitable for encoding; and
C) photoinducing said complex grating in the photosensitive medium using said phase mask.

16. The method according to claim 15, wherein sub-step A)(b) comprises expressing said modified index profile as:
Δn_{struct,mod}(z)=Δn_{offset}+Δnₘ(z)·exp(iθₘ(z))
wherein Δn_{struct,mod}(z) is the modified index profile, Δn_{offset} is an index offset making the modified index profile strictly positive, Δnₘ(z) is the modified apodization profile, and θₘ(z) is the modified phase profile.

17. The method according to claim 15, wherein the filtering of sub-step A)(c) comprises the substeps of:
vii. calculating a phase shift profile associated with the phase profile;
viii. calculating a Fourier spectrum of said phase shift profile; and
ix. filtering said Fourier spectrum of the phase shift profile through a filter function.

18. The method according to claim 17, wherein said filter function is set to 0 for spatial frequencies where said phase periodicities are present, and set to 1 otherwise.

19. The method according to claim 15, wherein the smooth apodization profile of sub-step A)(d) is set to a predetermined profile or to a spatially smoothed version of the modified apodization profile.

20. The method according to claim 15, wherein the repeating of sub-step A)(h) is carried out until the modified apodization profile is substantially free of fine structures and of phase periodicities.

21. The method according to claim 15, wherein the encoding of step B) comprises manufacturing said phase mask with corrugations having a phase profile related to the index profile suitable for encoding through a transfer function.

22. The method according to claim 21, wherein said transfer function is given by:
T=2 cos(πdz f)
where f is a spatial frequency and dz is a distance between two points along the phase mask from which pass two beams interfering in the photosensitive medium at a position z.

23. The method according to claim 15, wherein the photoinducing of step C) comprises the substeps of:
i. disposing the photosensitive medium along the phase mask in close proximity thereto; and
ii. projecting actinic radiation through said phase mask, said actinic radiation being diffracted by said phase mask to generate the complex optical grating, said complex optical grating being photoinduced into the photosensitive medium. A method for manufacturing a phase mask using such a design and a method for manufacturing a complex optical grating using such a phase mask are also provided.
